(19) United States
(12) Patent Application Publication
(10) Pub. No.: US 2008/0009141 A1
(43) Pub. Date: Jan. 10, 2008

(54) Methods to form SiCOH or SiCNH dielectrics and structures including the same

(75) Inventors: Geraud Dubois, Los Gatos, CA (US); Stephen M. Gates, Ossining, NY (US); Alfred Grill, White Plains, NY (US); Victor Y. Lee, San Jose, CA (US); Robert D. Miller, San Jose, CA (US); Son Nguyen, Yorktown Heights, NY (US); Vishnubhai Patel, Yorktown Heights, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 11/481,019

(22) Filed: Jul. 5, 2006

(51) Int. Cl. H01L 21/31; H01L 21/469

(52) U.S. Cl. 438/758

(57) ABSTRACT

Methods of forming dielectric films comprising Si, C, O and H atoms (SiCOH) or Si, C, N and H atoms (SiCHN) that have improved cohesive strength (or equivalently, improved fracture toughness or reduced brittleness), and increased resistance to water degradation of properties such as stress-corrosion cracking, Cu ingress, and other critical properties are provided. Electronic structures including the above materials are also included herein.

### RELATED APPLICATIONS

The present application is related to U.S. Ser. No. 11/132,108, filed May 18, 2005, as well as U.S. Pat. Nos. 6,147,009, 6,312,793, 6,441,491, 6,437,443, 6,541,398, 6,479,110 B2, 6,497,963, 6,768,200, 6,770,573, and U.S. Patent Application Publication Nos. 20050194619 and 20050276930 the contents of which are incorporated herein by reference.

### FIELD OF THE INVENTION

The present invention relates to a method of forming dielectric films comprising Si, C, O and H atoms (SiCOH) or Si, C, N and H atoms (SiCHN) that have improved cohesive strength (or equivalently, improved fracture toughness or reduced brittleness), and increased resistance to water degradation of properties such as stress-corrosion cracking, Cu ingress, and other critical properties. The present invention also relates to the use of the dielectric films as an intralevel or interlevel dielectric film, a dielectric cap or a hard mask/polish stop in back end of the line (BEOL) interconnect structures on ultra-large scale integrated (ULSI) circuits and related electronic structures. The present invention also relates to the use of the inventive dielectric material in an electronic device containing at least two conductors or an electronic sensing structure.

### BACKGROUND OF THE INVENTION

The continuous shrinking in dimensions of electronic devices utilized in ULSI circuits in recent years has resulted in increasing the resistance of the BEOL metallization as well as increasing the capacitance of the intralayer and interlayer dielectric. This combined effect increases signal delays in ULSI electronic devices. In order to improve the switching performance of future ULSI circuits, low dielectric constant (k) insulators and particularly those with k significantly lower than silicon oxide are needed to reduce the capacitances.

Most of the fabrication steps of very-large-scale-integration (“VLSI”) and ULSI chips are carried out by plasma enhanced chemical or physical vapor deposition techniques. The ability to fabricate a low k material by a plasma enhanced chemical vapor deposition (PECVD) technique using previously installed and available processing equipment will thus simplify its integration in the manufacturing process, reduce manufacturing cost, and create less hazardous waste. U.S. Pat. Nos. 6,147,009 and 6,497,963 assigned to the common assignee of the present invention, which are incorporated herein by reference in their entirety, describe a low dielectric constant material consisting of elements of Si, C, O and H atoms having a dielectric constant not more than 3.6 and which exhibits very low crack propagation velocities.

U.S. Pat. Nos. 6,312,793, 6,441,491 and 6,479,110 B2, assigned, to the common assignee of the present invention and incorporated herein by reference in their entirety, describe a multiphase low k dielectric material that consists of a matrix composed of elements of Si, C, O and H atoms, a phase composed mainly of C and H and having a dielectric constant of not more than 3.2.

Ultra low k dielectric materials having a dielectric constant of less than 2.7 (and preferably less than 2.3) are also known in the art. Key problems with prior art ultra low k SiCOH films include, for example: (a) they are brittle (i.e., low cohesive strength, low elongation to break, low fracture toughness); (b) liquid water and water vapor reduce the cohesive strength of the material even further. A plot of the cohesive strength, CS vs. pressure of water, P_{H2O} or % humidity, which is referred as a “CS humidity plot”, has a characteristic slope for each k value and material; (c) they tend to possess a tensile stress in combination with low fracture toughness, and hence tend to crack when in contact with water when the film is above some critical thickness; (d) they can absorb water and other process chemicals when porous, which in turn can lead to enhanced Cu electrochemical corrosion under electric fields, and ingress into the porous dielectric leading to electrical leakage and high conductivity between conductors; and (e) when C is bound as Si—CH₃ groups, prior art SiCOH dielectrics readily react with resist strip plasmas, CMP processes, and other integration processes, causing the SiCOH dielectric to be “damaged” resulting in a more hydrophilic surface layer.

For example, the silicate and organosilicate glasses tend to fall on a universal curve of cohesive strength vs. dielectric constant as shown in FIG. 1. This figure includes conventional oxides (point A), conventional SiCOH dielectrics (point B), conventional k=2.6 SiCOH dielectrics (point C), and conventional CVD ultra low k dielectrics with k about 2.2 (point D). The fact that both quantities are predominantly determined by the volume density of Si—O bonds explains the proportional variation between them. It also suggests that OSG materials with ultra low dielectric constants (e.g., k<2.4) are fundamentally limited to having cohesive strengths about 3 J/m² or less in a totally dry environment. Cohesive strength is further reduced as the humidity increases.

Another problem with prior art SiCOH films is that their strength tends to be degraded by H₂O. The effects of H₂O degradation on prior art SiCOH films can be measured using a 4-point bend technique as described, for example, in M. W. Lane, X. H. Liu, T. M. Shaw, “Environmental Effects on Cracking and Delamination of Dielectric Films”, IEEE Transactions on Device and Materials Reliability, 4, 2004, pp. 142-147. FIG. 2A is taken from this reference, and is a plot illustrating the effects that H₂O has on the strength of a typical SiCOH film having a dielectric constant, k of about 2.9. The data are measured by the 4-point bend technique in a chamber in which the pressure of water (PH₂O) is controlled and changed. Specifically, FIG. 2A shows the cohesive strength plotted vs. natural log (ln) of the H₂O pressure in the controlled chamber. The slope of this plot is approximately −1 in the units used. Increasing the pressure of H₂O decreases the cohesive strength. The region above the line in FIG. 2A, which is shaded, represents an area of cohesive strength that is difficult to achieve with prior art SiCOH dielectrics.

FIG. 2B is also taken from the M. W. Lane reference cited above, and is similar to FIG. 2A. Specifically, FIG. 2B is a plot of the cohesive strength of another SiCOH film measured using the same procedure as FIG. 2A. The prior art SiCOH film has a dielectric constant of 2.6 and the slope of this plot is about −0.66 in the units used. The region above the line in FIG. 2B, which is shaded, represents an area of cohesive strength that is difficult to achieve with prior art SiCOH dielectrics.

It is known that Si—C bonds are less polar than Si—O bonds. Further, it is known that organic polymer dielectrics have a fracture toughness higher than organosilicate glasses and are not prone to stress corrosion cracking (as are the Si—O based dielectrics). This suggests that the addition of more organic polymer content and more Si—C bonds to SiCOH dielectrics can decrease the effects of water degradation described above and increase the nonlinear energy dissipation mechanisms such as plasticity. Addition of more organic polymer content to SiCOH will lead to a dielectric with increased fracture toughness and decreased environmental sensitivity.

It is known in other fields that mechanical properties of some materials, for example, organic elastomers, can be improved by certain crosslinking reactions involving added chemical species to induce and form crosslinked chemical bonds. This can increase the elastic modulus, glass transition temperature, and cohesive strength of the material, as well as, in some cases, the resistance to oxidation, resistance to water uptake, and related degradations.

In view of the above drawbacks with prior art low and ultra low k SiCOH dielectrics, there exists a need for providing a method of forming porous SiCOH dielectric films having a dielectric constant value of about 3.2 or less with a significantly increased cohesive strength vs. k curve that lies above the universal curve defined in FIG. 1. For the particular case in FIG. 1, the fracture toughness and the cohesive strength are equivalent. There further exists a need for developing a method of forming a porous SiCOH dielectric film with Si—C bonding, increased resistance to water, particularly within the shaded regions of FIGS. 2A and 2B, and favorable mechanical properties that allow for such films to be used in new applications in ULSI devices.

### SUMMARY OF THE INVENTION

The present invention provides a low k dielectric material that consists of a matrix (or skeleton) composed of the elements Si, C, O and H atoms and a multitude of nanometer size pores inside this matrix. Such a dielectric material is hereinafter referred to as a SiCOH dielectric.

In one embodiment of the present invention, a low cost, simple method to fine tune or adjust the concentration of desired bonds (i.e., Si—R—Si bonds) in the skeleton of a porous SiCOH film is provided. By adjusting the Si—R—Si bonds, the cohesive strength in 50% humidity, stress, resistance to integration damage and other like properties will be improved. In the above formula, R is —[CH₂]ₙ— where n is greater than or equal to one. In one preferred embodiment, the SiCOH dielectric includes Si—[CH₂]ₙ—Si wherein n is 1-3.

The present method of forming porous SiCOH dielectric films is more manufacturable than prior art methods due to the choice of precursors. Moreover, the present invention provides a solution to the problem of uniformity of the deposited SiCOH film across the wafer when using two or three precursors.

Generally, the present invention provides a method to make a porous SiCOH dielectric having improved and adjustable properties, including new Si—C bonding. Prior art methods to make improved porous SiCOH dielectrics use high cost precursors, or high boiling point precursors, and do not allow the concentration of desired Si—C bonds to be adjusted or controlled in the skeleton of the porous SiCOH film.

In general terms, one method of the present invention comprises the steps of:

providing a substrate in a reactor chamber;

flowing at least one precursor into said reactor chamber, wherein said at least one precursor is a cyclic carbosilane or oxycarbosilane;

depositing a dielectric film onto said substrate; and

optionally performing an energetic treatment step to provide a porous dielectric film on top of said substrate.

In general terms, a second method of the present invention comprises the steps of:

providing at least a first precursor and a second precursor into a reactor chamber, wherein at least one of the precursors is a hydrocarbon porogen and the other of said precursors is a cyclic carbosilane or oxycarbosilane;

depositing a film comprising a first phase and a second phase; and

removing said porogen from said film to provide a porous dielectric film.

In addition to the above, the SiCOH dielectric material of the present application has a plot of cohesive strength (CS) vs. % humidity that shows a weak dependence on humidity. That is, at a given dielectric constant, the SiCOH dielectric materials of this invention have a smaller slope than the plots shown in FIGS. 2A and 2B, and the cohesive strength at a specific value of PH₂O therefore lies above the line in FIG. 2A or 2B, in the shaded regions. By “weak dependence” it is meant that the inventive SiCOH dielectrics have a lower slope in the plot than prior art materials. Within the invention, this is achieved by decreasing the number of reactive sites (Si—O—Si). The slope of the CS vs In PH₂O curves is determined by the density of reactive Si—O—Si sites. While decreasing the number of Si—O—Si sites decreases the sensitivity to moisture, it also decreases the cohesive strength which depends linearly on the Si—O—Si bond density.

Moreover, the porous SiCOH dielectric film of the present application is very stable towards H₂O vapor (humidity) exposure, including a resistance to crack formation in water.

The present invention also provides a related film of the general composition SiCNH which is useful as a low k Cu cap, and methods to make this film from a single cyclic precursor containing Si, C and N in a ring. Examples of such precursors are 2,2,5,5-tetramethyl-2,5-disila-1-azacyclopentane, or a related azacyclopentane, which are cyclic molecules containing one N atom in a five member ring with two Si and two C atoms.

The SiCNH film of the present invention, which typically has a dielectric constant of about 6.0 or less, is prepared utilizing the following processing steps:

providing a substrate in a reactor chamber;

flowing at least one precursor into said reactor chamber, said at least one precursor is a cyclic compound that contains at least one N atom in a ring structure with Si and C atoms; and

depositing a dielectric film comprising atoms of Si, C, N and H from said at least one precursor.

The SiCNH dielectric films of the present application can be dense (i.e., non-porous) or porous. Porous SiCNH dielectric films are formed by including a porogen, as a precursor, and after deposition removing the porogen from the as-deposited film.

In some embodiments of forming the SiCNH dielectric, a flow of a gas is added to said at least one precursor which comprises at least one of a NH₃, CO, CO₂, O₂, N₂O, O₃, N₂ and an inert gas.

### BRIEF DESCRIPTION OF THE DRAWINGS

FIG. 1 is a universal curve of cohesive strength vs. dielectric constant for prior art dielectrics.

FIGS. 2A-2B show the cohesive strength plotted vs. natural log (In) of the H₂O pressure in a controlled chamber for prior art SiCOH dielectrics.

FIG. 3 is a universal curve of cohesive strength vs. dielectric constant including prior art dielectrics as shown in FIG. 1 as well as the inventive SiCOH dielectric material.

FIGS. 4A-4B are Fourier Transform Infrared (FTIR) spectra of a SiCOH film containing Si—CH₂—Si bonds, and illustrate the detection of said bonds by an FTIR peak between 1350-1370 cm⁻¹. FIG. 4A is a full spectrum, while FIG. 4B is an expanded spectrum from 0 to 1700 cm⁻¹. In each of FIGS. 4A and 4B, the spectrum (a) is from an as-deposited SiCOH dielectric film, and spectrum (b) is the same film after annealing at 430° C.

FIG. 5 is an FTIR spectrum of a porous SiCOH film after annealing at 430° C. for 4 hours made in accordance with the second embodiment of the present invention. The peak as 1351 cm⁻¹ is assigned to absorbance by S₁—CH₂—Si bonds.

FIG. 6 is an enlarged, cross-sectional view of an electronic device of the present invention that includes the inventive dielectric film as both the intralevel dielectric layer and the interlevel dielectric layer.

FIG. 7 is an enlarged, cross-sectional view of the electronic structure of FIG. 6 having an additional diffusion barrier dielectric cap layer deposited on top of the inventive dielectric film, said diffusion barrier can be one of the inventive films (i.e., SiCOH or SiCHN).

FIG. 8 is an enlarged, cross-sectional view of the electronic structure of FIG. 7 having an additional RIE hard mask/polish-stop dielectric cap layer and a dielectric cap diffusion barrier layer deposited on top of the polish-stop layer, said dielectric cap diffusion barrier can be one of the inventive films.

FIG. 9 is an enlarged, cross-sectional view of the electronic structure of FIG. 8 having additional RIE hard mask/polish-stop dielectric layers deposited on top of the dielectric film of the present invention.

FIG. 10 is a pictorial representation (through a cross sectional view) illustrating an electronic structure including at least two conductors and the inventive dielectric material.

FIGS. 11A-11B are pictorial representations (through cross sectional views) illustrating electronic structures including a sensing element and the inventive dielectric material.

### DETAILED DESCRIPTION OF THE INVENTION

In one embodiment of the present invention, a porous dielectric material that comprises a matrix of a hydrogenated oxidized silicon carbon material (SiCOH) comprising elements of Si, C, O and H in a covalently bonded tri-dimensional network and having a dielectric constant of about 3.2 or less is provided. The term “tri-dimensional network” is used throughout the present application to denote a SiCOH dielectric material which includes silicon, carbon, oxygen and hydrogen that are interconnected and interrelated in the x, y, and z directions.

In particular, the present invention provides SiCOH dielectrics that have a covalently bonded tri-dimensional network structure which includes C bonded as S₁—CH₃ and also C bonded as Si—R—Si, wherein R is —[CH₂]ₙ— where n is greater than or equal to 1, preferably n is 1-3. In some embodiments of the present invention, the inventive dielectric material has a fraction of the total carbon atoms that is bonded as Si—R—Si between 0.01 and 0.99.

The SiCOH dielectric material of the present invention comprises between about 5 and about 40, more preferably from about 10 to about 20, atomic percent of Si; between about 5 and about 50, more preferably from about 15 to about 40, atomic percent of C; between 0 and about 50, more preferably from about 10 to about 30, atomic percent of O; and between about 10 and about 55, more preferably from about 20 to about 45, atomic percent of H.

In some embodiments, the SiCOH dielectric material of the present invention may further comprise F and/or N. In yet another embodiment of the present invention, the SiCOH dielectric material may optionally have the Si atoms partially substituted by Ge atoms. The amount of these optional elements that may be present in the inventive dielectric material of the present invention is dependent on the amount of precursor that contains the optional elements that is used during deposition.

The SiCOH dielectric material of the present invention contains molecular scale voids (i.e., nanometer-sized pores) between about 0.3 to about 10 nanometers in diameter, and most preferably between about 0.4 and about 5 nanometers in diameter, which reduce the dielectric constant of the SiCOH dielectric material. The nanometer-sized pores occupy a volume between about 0.5% and about 50% of a volume of the material.

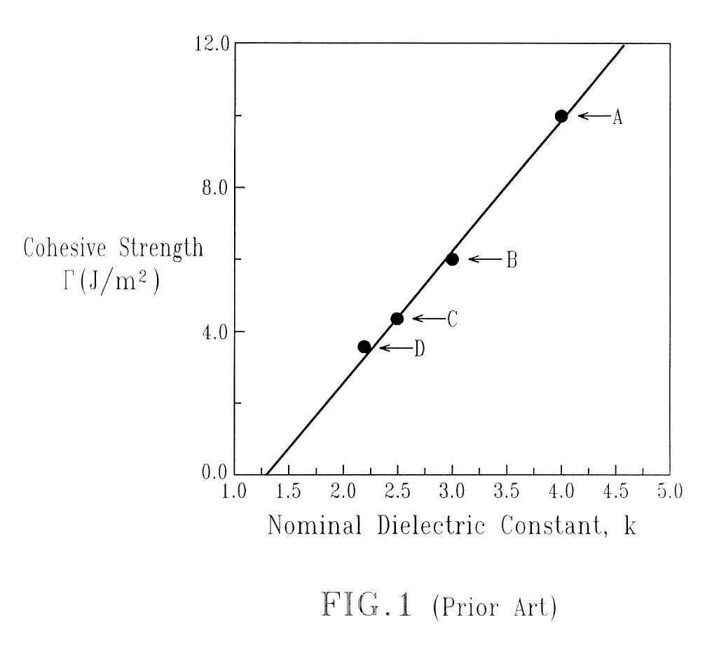

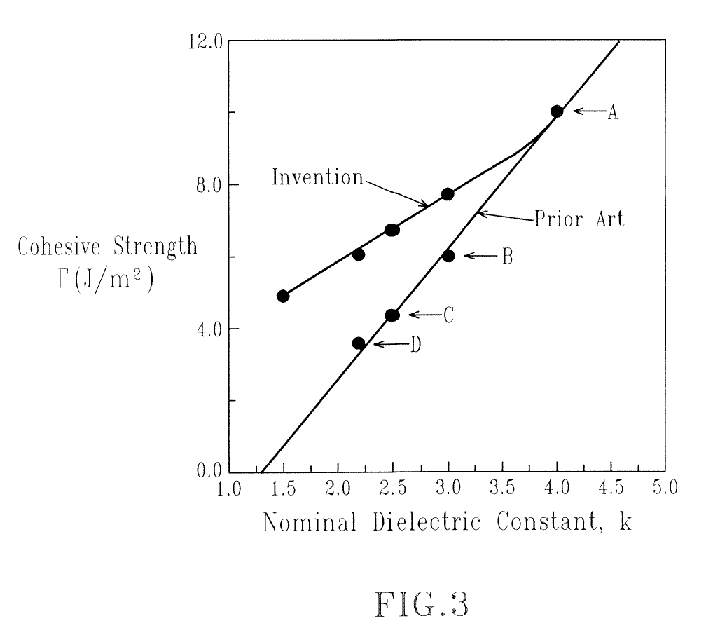

FIG. 3 shows a universal curve of cohesive strength vs. dielectric constant including prior art dielectrics as shown in FIG. 1 as well as the inventive SiCOH dielectric material. The plot in FIG. 3 shows that the inventive SiCOH dielectric has a higher cohesive strength than prior art dielectrics at equivalent values of k. In FIGS. 1 and 3, the k is reported as the relative dielectric constant.

The inventive SiCOH dielectric of the present invention has more carbon bonded in organic groups bridging between two Si atoms compared to the Si—CH₃ bonding characteristic of prior art SiCOH and pSiCOH dielectrics.

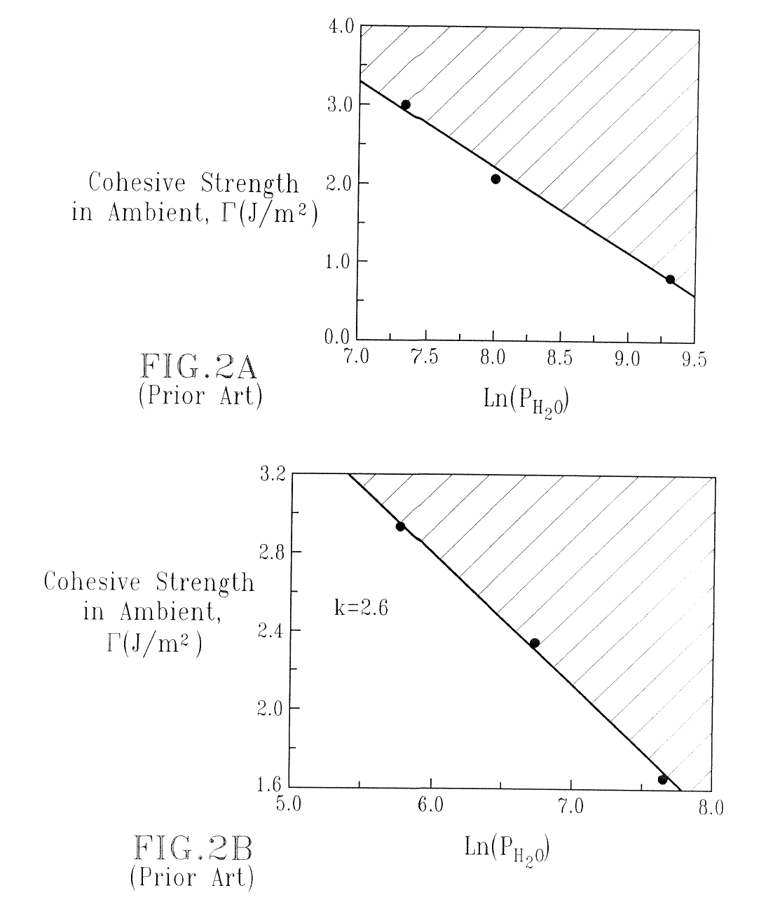

In addition, the SiCOH dielectric materials of the present invention are hydrophobic with a water contact angle of greater than 70°, more preferably greater than 80° and exhibit a relatively high cohesive strength. This property of the present SiCOH dielectric material is shown schematically in the shaded regions of FIGS. 2A and 2B.

The inventive SiCOH dielectric materials are typically deposited using plasma enhanced chemical vapor deposition (PECVD). In addition to PECVD, the present invention also contemplates that the SiCOH dielectric materials can be formed utilizing chemical vapor deposition (CVD), high-density plasma (HDP), pulsed PECVD, spin-on application, or other related methods.

In the deposition process, the inventive SiCOH dielectric material is formed by providing at least a cyclic carbosilane or oxycarbosilane precursor (liquid, gas or vapor) comprising atoms of Si, C, O, and H, and optionally an inert carrier such as He or Ar, into a reactor, preferably the reactor is a PECVD reactor, and then depositing a film derived from said cyclic carbosilane or oxycarbosilane precursor onto a suitable substrate utilizing conditions that are effective in forming the SiCOH dielectric material of the present invention.

In selected embodiments of this invention, the as-deposited film comprises two phases. One of the phases of the as-deposited film is the sacrificial hydrocarbon phase comprised of C and H, while the other phase (i.e., the stable skeleton phase) is comprised of Si, O, C and H. The present invention yet further provides for optionally an oxidizing agent such as O₂, O₃, N₂O, CO₂ or a combination thereof to the gas mixture, thereby stabilizing the reactants in the reactor and improving the properties and uniformity of the dielectric film deposited on the substrate.

Within the present invention, the cyclic carbosilane precursor or oxycarbosilane comprises at least one of the following compounds: 1,1-dimethyl-1-silacyclopentane, 1,3-disilylcyclobutane, methyl-1-silacyclopentane, silacyclopentane, silacyclobutane, methylsilacyclobutanes, silacyclohexane, methylsilacyclohexanes, tetramethyl-disila-furan, disila-furan, derivatives of disila-furan containing 1, 2, 3 or 4 methyl or other alkyl groups, methoxy derivatives of the aforementioned cyclic precursors, and related Si—C containing molecules.

Alternatively, the cyclic carbosilane may contain an unsaturated ring to make this precursor more reactive in the deposition plasma (for example, a low power plasma) such as, for example, 1,1-diethoxy-1-silacyclopentene, 1,1-dimethyl-3-silacyclopentene, 1,1-dimethyl-1-silacyclopent-3-ene, 1-sila-3-cyclopentene, vinylmethylsilacyclopentene, methoxy derivatives of silacyclopentene, other derivatives of silacyclopentene, and related other cyclic carbosilane precursors.

The structures of some preferred cyclic carbosilanes are shown below to illustrate the types of cyclic compounds contemplated by the present invention (the illustrated structures thus do not limit the present invention in any way):

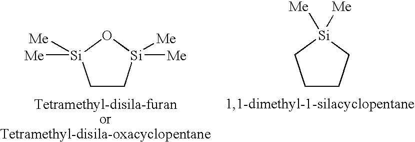

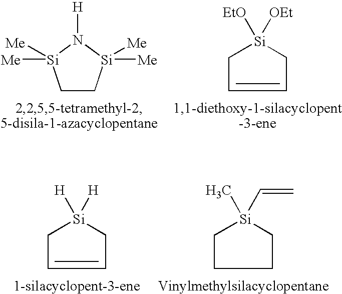

The cyclic compounds mentioned above are preferred in the present invention because these precursors have a relatively low boiling point, and they include the Si—[CH₂]ₙ—Si bonding group.

A second precursor that is used in the present invention is a hydrocarbon (i.e., a compound containing C and H atoms, and optionally N and/or F) molecule, as described in U.S. Pat. Nos. 6,147,009, 6,312,793, 6,441,491, 6,437,443, 6,541,398, 6,479,110 B2, and 6,497,963, the contents of which are incorporated herein by reference. The hydrocarbon molecules are used as porogens in the present invention. The hydrogen precursor may be a liquid or a gas.

Optionally, a SiCOH skeleton precursor (e.g., third precursor) comprising an alkoxysilane or cyclic siloxane precursor may be added to the reactor. Examples of such SiCOH skeleton precursors include, for example, diethoxymethylsilane, octamethyltetrasiloxane, tetramethyltetrasiloxane, trimethylsilane, or any other common alkylsilane or alkoxysilane (cyclic or linear) molecule.

Optionally, a precursor (gas, liquid or gas) comprising Ge may also be used.

Other functional groups, as described in the examples below, can be used to form a bridging group between two Si atoms.

The cyclic carbosilane precursors mentioned above with nitrogen can also be used to deposit a SiCHN cap film with the addition of gases containing nitrogen (e.g., NH₃, N₂ or N₂H₂). With the presence of the N bridging between two Si atoms, the SiCHN film will be more stable thermally and towards plasmas and other kinds of integration damage.

The method of the present invention may further comprise the step of providing a parallel plate reactor, which has a conductive area of a substrate chuck between about 85 cm² and about 750 cm², and a gap between the substrate and a top electrode between about 1 cm and about 12 cm. A high frequency RF power is applied to one of the electrodes at a frequency between about 0.45 MHz and about 200 MHz. Optionally, an additional RF power of lower frequency than the first RF power can be applied to one of the electrodes.

The conditions used for the deposition step may vary depending on the desired final dielectric constant of the SiCOH dielectric material of the present invention. Broadly, the conditions used for providing a stable dielectric material comprising elements of Si, C, O, H that has a dielectric constant of about 3.2 or less, a tensile stress of less than 45 MPa, an elastic modulus from about 2 to about 15 GPa, and a hardness from about 0.2 to about 2 GPa include: setting the substrate temperature at between about 100° C. and about 425° C.; setting the high frequency RF power density at between about 0.1 W/cm² and about 2.0 W/cm²; setting the first liquid precursor flow rate at between about 10 mg/min and about 5000 mg/min, optionally setting the second liquid precursor flow rate at between about 10 mg/min to about 5,000 mg/min; optionally setting the third liquid precursor flow rate at between about 10 mg/min to about 5000 mg/min; optionally setting the inert carrier gases such as helium (or/and argon) flow rate at between about 10 sccm to about 5000 sccm; setting the reactor pressure at a pressure between about 1000 mTorr and about 10,000 mTorr; and setting the high frequency RF power between about 50 W and about 1000 W. Optionally, an ultra low frequency power may be added to the plasma between about 20 W and about 400 W.

When an oxidizing agent is employed in the present invention, it is provided into the PECVD reactor at a flow rate between about 10 sccm to about 1000 sccm.

While liquid precursors are used in the above example, it is known in the art that gas phase precursors can also be used for the deposition.

The film resulting from the above processes is called herein the “as-deposited film”.

According to the present invention, the fabrication of the stable SiCOH dielectric materials of the present invention may require a combination of several steps:
the material is deposited on a substrate in a 1^{st} step, using deposition tool parameters similar to those given below in the process embodiments, forming the as-deposited film; and then
the material is cured or treated using thermal, UV light, electron beam irradiation, chemical energy, or a combination of more than one of these, forming the final film having the desired mechanical and other properties described herein. For example, after deposition a treatment of the SiCOH film (using both thermal energy and a second energy source) may be performed to stabilize the film and obtain improved properties. The second energy source may be electromagnetic radiation (UV, microwaves, etc.), charged particles (electron or ion beam) or may be chemical (using atoms of hydrogen, or other reactive gas, formed in a plasma). The conditions for these treatments are well known to those skilled in the art.

In a preferred treatment, the substrate (containing the film deposited according to the above process) is placed in a ultraviolet (UV) treatment tool, with a controlled environment (vacuum or ultra pure inert gas with a low O₂ and H₂O concentration). A pulsed or continuous UV source may be used.

Within the invention, the UV treatment tool may be connected to the deposition tool (“clustered”), or may be a separate tool.

As is known in the art, the two process steps will be conducted within the invention in two separate process chambers that may be clustered on a single process tool, or the two chambers may be in separate process tools (“declustered”). For some embodiments of the present porous SiCOH films, the cure step may involve removal of a sacrificial hydrocarbon fraction. The hydrocarbon fraction may be deposited from the carbosilane precursors or may be deposited from an additional porogen precursor added to the deposition chamber. Suitable sacrificial hydrocarbon precursors that can be employed in the present invention include, but are not limited to the second precursors that are mentioned in U.S. Pat. Nos. 6,147,009, 6,312,793, 6,441,491, 6,437,443, 6,541,398, 6,479,110 B2, and 6,497,963, the contents of which are incorporated herein by reference. Preferred hydrocarbon precursors comprise one of bicycloheptadiene, hexadiene, and bifunctional diene hydrocarbon molecules.

In other embodiments of the present porous SiCOH films, the cure step may cause rearrangement of the film structure to create more open volume, and hence to lower the dielectric constant, without removal of a sacrificial fraction or phase.

In another embodiment of the present invention, a dielectric film of the general composition SiCNH is provided. In this embodiment of the present invention, a dense or porous dielectric material comprising elements of Si, C, N and H in a covalently bonded tri-dimensional network and having a dielectric constant of about 6 or less is provided. The term “tri-dimensional network” is used throughout the present application to denote a SiCNH dielectric material which includes silicon, carbon, nitrogen and hydrogen that are interconnected and interrelated in the x, y, and z directions.

The SiCNH dielectric film of the present invention can be formed utilizing basically the same processing conditions as mentioned above. In the deposition step, a single cyclic precursor containing Si, C and N in a ring structure is used. Examples include, but are not limited to: 2,2,5,5-tetramethyl-2,5-disila-1-azacyclopentane, or a related azacyclopentane.

In a typical deposition process, a substrate is placed in a PECVD deposition chamber, and a flow of the cyclic precursor containing Si, C and N in a ring structure is stabilized. The conditions used in the deposition step may include a precursor flow of 100-3000 mg/m for all precursors, a He gas flow of 10-3000 sccm, and the optional use of N₂ with a flow from 10-1000 sccm said flows are stabilized to reach a reactor pressure of 1-10 Torr. The wafer chuck temperature is typically set between 100°-400° C., with 300°-400° C. range preferred. The high frequency RF power which is typically in the range from 50-1,000 W is applied to a showerhead, and the low frequency RF (LRF) power may be used in the range 10-500 W, according to the density desired for the film.

As is known in the art, each of the above process parameters may be adjusted within the invention. For example, the wafer chuck temperature may be between 100°-450° C. As is known in the art, gases such as CO₂ may be added, and He may be replaced by gases such as, for example, Ar, O₃ or N₂O, or another noble gas. C₂H₄ may also be used in forming the inventive SiCNH dielectric material. Again, other functional groups, as described in the examples below, can be used to form a bridging group between two Si atoms.

The SiCNH dielectric material of the present invention comprises between about 5 and about 40, more preferably from about 10 to about 20, atomic percent of Si; between about 5 and about 50, more preferably from about 15 to about 40, atomic percent of C; between 0 and about 50, more preferably from about 10 to about 30, atomic percent of N; and between about 10 and about 55, more preferably from about 20 to about 45, atomic percent of H.

In some embodiments, the SiCNH dielectric material of the present invention may further comprise F. In yet another embodiment of the present invention, the SiCNH dielectric material may optionally have the Si atoms partially substituted by Ge atoms. The amount of these optional elements that may be present in the inventive dielectric material of the present invention is dependent on the amount of precursor that contains the optional elements that is used during deposition.

The SiCNH dielectric material of the present invention may contain molecular scale voids (i.e., nanometer-sized pores) between about 0.3 to about 10 nanometers in diameter, and most preferably between about 0.4 and about 5 nanometers in diameter, which reduce the dielectric constant of the SiCNH dielectric material. The nanometer-sized pores occupy a volume between about 0.5% and about 50% of a volume of the material. The voids are created by including one of the above mentioned porogens within the deposition process.

The SiCNH dielectric material of the present invention described above may be used, for example, to form layer 62 shown in FIGS. 7, 8, and 9. This layer is the diffusion barrier/etch stop between layers of patterned metal conductors.

The following are examples illustrating material and processing embodiments of the present invention.

### EXAMPLE 1

### First Method Embodiment

In this example, a porous SiCOH material with a dielectric constant k=2.4 was made in a two step process. In the deposition step, one cyclic carbosilane or oxycarbosilane precursor was selected to have a low boiling point, low cost, and to provide bonding of the form Si—[CH₂]ₙ—Si. Specifically, 1,1-dimethyl-1-silacyclopentane was used. The conditions used in the deposition step included a precursor flow of 8 sccm for the carbosilane 1,1-dimethyl-1-silacyclopentane, and 0.5 sccm for oxygen (O₂). The substrate was placed in the reactor and the precursor's flows were stabilized to reach a reactor pressure of 0.5 Torr. The wafer chuck temperature was set to about 180° C. RF power at 13.6 MHz frequency was applied at a power of 30 W. After deposition, the film was annealed at 4300 for 4 hours, and a dielectric constant of 2.4 was measured at 150° C. Generally, other energetic post treatments may be used at this step, within the invention. In this embodiment, the energetic post treatment (or cure) step may cause rearrangement of the film structure to create more open volume, and hence to lower the dielectric constant, without removal of a sacrificial phase.

As is known in the art, each of the above process parameters may be adjusted within the invention. For example, the wafer chuck temperature may be between 100°-400° C. As is known in the art, gases such as He or CO₂ may be added, and these may be replaced by gases such as Ar, or N₂O or another noble gas.

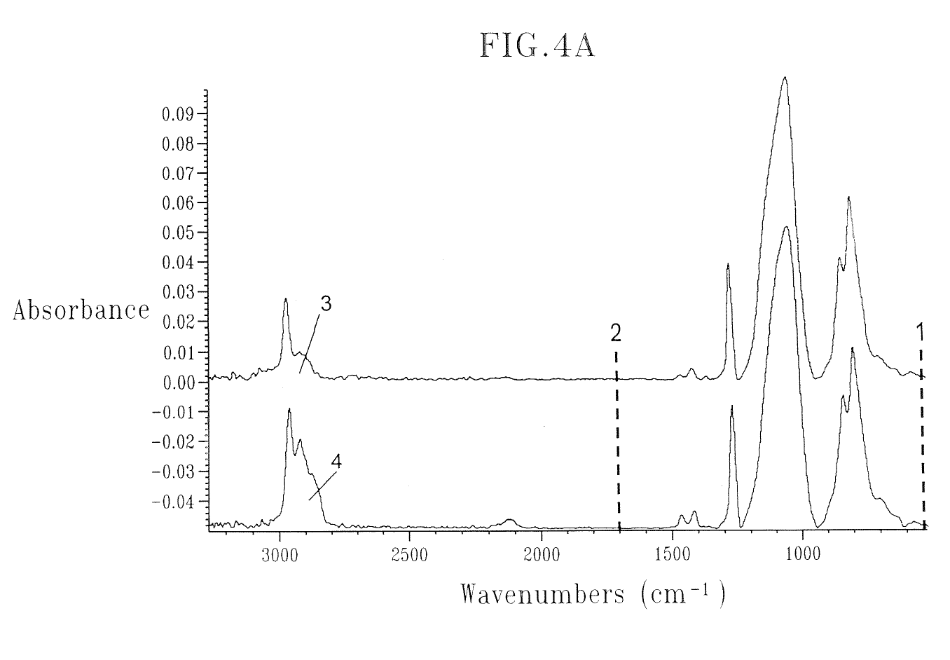

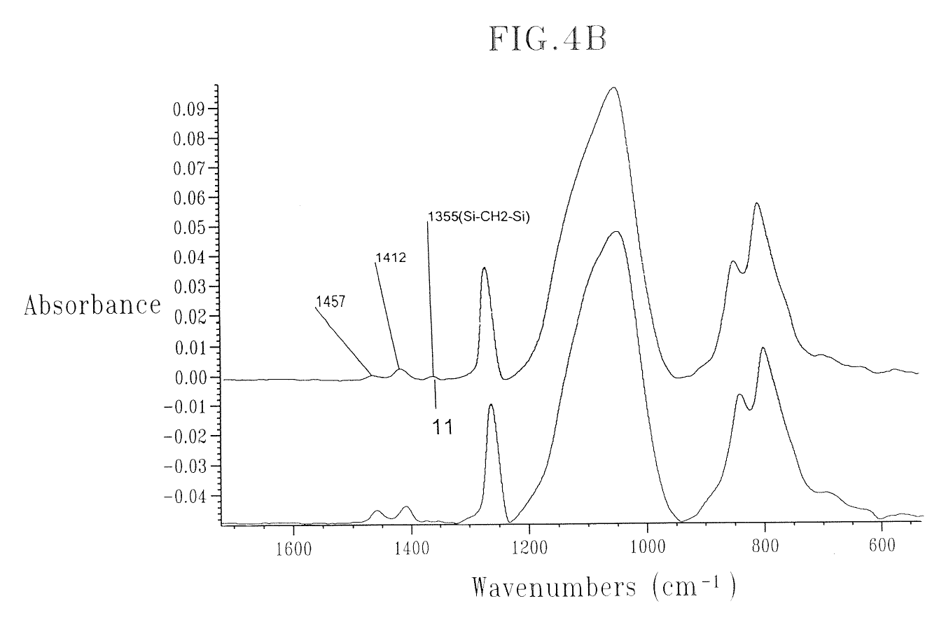

The FTIR spectrum of this SiCOH dielectric material is shown, for example, in FIGS. 4A and 4B. Specifically, FIGS. 4A-4B are FTIR spectrum of a SiCOH film containing Si—CH₂—Si bonds, and illustrate the detection of said bonds by an FTIR peak between 1350-1370 cm⁻¹. FIG. 4A is a full spectrum, while FIG. 4B is an expanded spectrum from 0 to 1700 cm⁻¹. In each of FIGS. 4A and 4B, the spectrum (a) is from an as-deposited SiCOH dielectric film, and spectrum (b) is the same film after annealing.

In FIG. 4A, the dashed lines 1 and 2 show the limits of the expanded spectra in FIG. 4B. The features labeled 3 and 4 are absorbance peaks assigned to the C—H stretching vibrations of the CHₓ hydrocarbon species. The reduced intensity of peak 4 compared to peak 3 indicates that some of the CHₓ species (CHₓ fraction) have been removed by the thermal treatment, to create open volume (small scale porosity) in the film. Note that no second porogen precursor has been used in this embodiment. In FIG. 4B, the feature labeled 11 is an absorbance peak assigned to Si—CH₂—Si groups, one of the characteristic structures of the SiCOH materials of this invention.

Generally a number of cyclic carbosilane precursors may be used, including for example 1,1-dimethyl-1-silacyclopentane, methyl-1-silacyclopentane, silacyclopentane, silacyclobutane, methylsilacyclobutanes, silacyclohexane, methylsilacyclohexanes, tetramethyl-disila-furan, disila-furan, methoxy derivatives of the aforementioned cyclic precursors, or derivatives of disila-furan containing 1, 2, 3 or 4 R groups, where R is selected from methyl, ethyl, vinyl, propyl, allyl, butyl.

### EXAMPLE 2

### Second Method Embodiment

In this example, a porous SiCOH material with k=2.4 was made in a two step process. In the deposition step, two precursors were used. The cyclic precursor was selected to have a low boiling point, low cost, and to provide bonding of the form Si—[CH₂]ₙ—Si. The cyclic carbosilane precursor employed was 1,1-dimethyl-1-silacyclopentane. Bicycloheptadiene (BCHD) was used as a second precursor and serves as a porogen in this method. The conditions used in the deposition step included a precursor flow of 5 sccm for 1,1-dimethyl-1-silacyclopentane, and 2 sccm for the BCHD, and 0.5 sccm for oxygen (O₂). The substrate was placed in the reactor and the precursor's flows were stabilized to reach a reactor pressure of 0.5 Torr. The wafer chuck temperature was set to about 180° C. RF power at 13.6 MHz frequency was applied at a power of 50 W. After deposition, the film was annealed at 430° C. for 4 hours, and the FTIR data of FIG. 5 were collected, and the dielectric constant of 2.4 was measured at 150° C. Shown in FIG. 5 is an FTIR peak at 1351 cm⁻¹, which confirms the presence of Si—CH₂—Si species in the film.

As is known in the art, each of the above process parameters may be adjusted within the invention. For example, the wafer chuck temperature may be between 100°-400° C. As is known in the art, gases such as He or CO₂ may be added, and these may be replaced by gases such as Ar, O₂ or N₂O, or another noble gas. Generally, an energetic post treatment step may be used after deposition, and all the cyclic carbosilanes or oxycarbosilane named above in the first embodiment may be used.

### EXAMPLE 3

### Third Method Embodiment

In this example, a porous SiCOH material, with k greater than or equal to 1.8, and having enhanced Si—R—Si bridging carbon or other organic functions bridging between two Si atoms was made using three precursors in a two step process. Here, R is used to represent bridging organic groups such as CH₂, CH₂—CH₂, CH₂—CH₂—CH₂ and more generally [CH₂]ₙ. In the deposition step, three precursors are used with one of these being a hydrocarbon porogen (used according to methods known in the art). The porogen may be bicycloheptadiene (BCHD), hexadiene (HXD), or other molecules described, for example, in U.S. Pat. Nos. 6,147,009, 6,312,793, 6,441,491, 6,437,443, 6,441,491, 6,541,398, 6,479,110 B2, and 6,497,963. Another one of the precursors used in this example was a SiCOH skeleton precursor DEMS (diethoxymethylsilane). The third precursor, which was selected to provide a desired amount of bonding of the form Si—[CH₂]ₙ—Si, was 1,1-dimethyl-1-silacyclopentane, although other cyclic carbosilanes may be used, including methyl-1-silacyclopentane, 1,3-disilylcyclobutane, silacyclopentane, silacyclobutane, methylsilacyclobutanes, silacyclohexane, methylsilacyclohexanes, tetramethyl-disila-furan, disila-furan, methoxy derivatives of the aforementioned cyclic precursors, or derivatives of disila-furan containing 1, 2, 3 or 4 R groups, where R is selected from methyl, ethyl, vinyl, propyl, allyl, butyl.

Within the inventive method, the ratio R1 is the ratio of carbosilane precursor to SiCOH skeleton precursor in the reactor, and the ratio R2 is the ratio of porogen precursor to SiCOH skeleton precursor in the reactor. R1 determines the concentration of Si—R—Si bridging carbon in the final porous SiCOH film. R1 may be in the range 0.01 to 100, but commonly is in the range 0.05-1. R2 determines the volume % porosity and hence the dielectric constant in the final porous SiCOH film. R2 may be in the range 0.1 to 10, but commonly is in the range 0.5-2.

The conditions used in the deposition step included a precursor flow of 100-3000 mg/m for all precursors, a He gas flow of 10-3000 sccm, and a porogen flow of about 50-3000 mg/m, and optionally the oxygen flow from 10-1000 sccm said flows were stabilized to reach a reactor pressure of 0.1-20 Torr, and preferably 1-10 Torr. The wafer chuck temperature was set between 100°-400° C., with 200°-300° C. range preferred. The high frequency RF power was in the range 50-1,000 W applied to the showerhead, and the low frequency RF (LRF) power was 0 W so that no LRF was applied to the substrate. The film deposition rate was in the range 200 to 10,000 Angstrom/min.

As is known in the art, each of the above process parameters may be adjusted within the invention. For example, the wafer chuck temperature may be between 100°-350° C. As is known in the art, gases such as CO₂ may be added, and He may be replaced by gases such as Ar, O₃ or N₂O or another noble gas.

After deposition, the film was treated in an energetic post treatment step that includes at least one of thermal, ultraviolet light, electron beam, or other energy source. This step creates a porous film.

### EXAMPLE 4

### Fourth Method Embodiment

In a fourth embodiment, a process similar to the first embodiment (carbosilane 1,1-dimethyl-1-silacyclopentane and oxygen O₂ process) was used, but the cyclic carbosilane precursor was selected from: 1,1-dimethyl-1-silacyclopentane, methyl-1-silacyclopentane, silacyclopentane, silacyclobutane and methylsilacyclobutanes, silacyclohexane and methylsilacyclohexanes, tetramethyl-disila-furan, disila-furan, derivatives of disila-furan containing 1, 2, 3 or 4 methyl groups, methoxy derivatives of the aforementioned cyclic carbosilanes, and related Si—C containing molecules. Alternatively, the carbosilane may contain an unsaturated ring to make this precursor more reactive in the deposition plasma (for example a low power plasma) such as 1,1-diethoxy-1-silacyclopentene, 1,1-dimethyl-3-silacyclopentene, 1-sila-3-cyclopentene, vinylmethylsilacyclopentene, methoxy derivatives of these unsaturated cyclic carbosilanes and related other cyclic carbosilane precursors.

The conditions used in the deposition step included a precursor flow of 100-3000 mg/m for all precursors, a He gas flow of 10-3000 sccm, and a porogen flow of about 50-3000 mg/m, and optionally the oxygen flow from 10-1000 sccm said flows were stabilized to reach a reactor pressure of 1-10 Torr. The wafer chuck temperature was set between 100°-350° C., with 250°-300° C. range preferred. The high frequency RF power was in the range 50-1,000 W applied to the showerhead, and the low frequency RF (LRF) power was 0 W so that no LRF was applied to the substrate. The film deposition rate was in the range 200 to 10,000 Angstrom/min. After deposition, an energetic post treatment step may be used to produce the final porous dielectric film.

As is known in the art, each of the above process parameters may be adjusted within the invention. For example, the wafer chuck temperature may be between 100°-400° C. As is known in the art, gases such as CO₂ may be added, and He may be replaced by gases such as Ar, O₃ or N₂O, or another noble gas. The film of this embodiment was generally SiCH in composition, with an optional small O content.

### EXAMPLE 5

### Fifth Method Embodiment

In a fifth embodiment, a process was used to deposit a film of SiCNH composition using cyclic precursor including nitrogen, such as 2,2,5,5-tetramethyl-2,5-disila-1-azacyclopentane, or a related azacyclopentane.

The conditions used in the deposition step included a precursor flow of 100-3000 mg/m for all precursors, a He gas flow of 10-3000 sccm, and a porogen flow of about 50-3000 mg/m. For this film of SiCNH composition optionally NH₃ (ammonia) is added at a flow from 10-1000 sccm. Said flows were stabilized to reach a reactor pressure of 1-10 Torr. The wafer chuck temperature was set between 100°-400° C., with 350° C. preferred. The high frequency RF power was in the range 50-1,000 W applied to the showerhead, and the low frequency RF (LRF) power was 0 W so that no LRF was applied to the substrate. The film deposition rate was in the range 200 to 10,000 Angstrom/min. After deposition, an energetic post treatment step may be used to produce the final dielectric film, but is not required.

As is known in the art, each of the above process parameters may be adjusted within the invention. For example, the wafer chuck temperature may be between 100°-400° C. As is known in the art, gases such as N₂ may be added, and He may be replaced by gases such as Ar, or another noble gas. The film of this embodiment was generally SiCNH in composition.

Electronic Devices

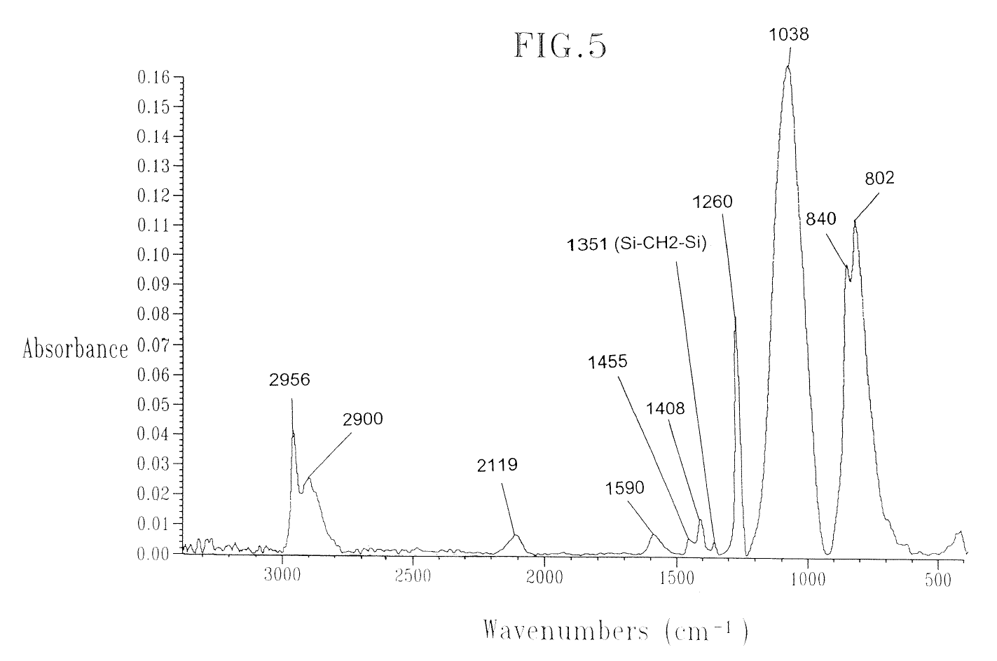

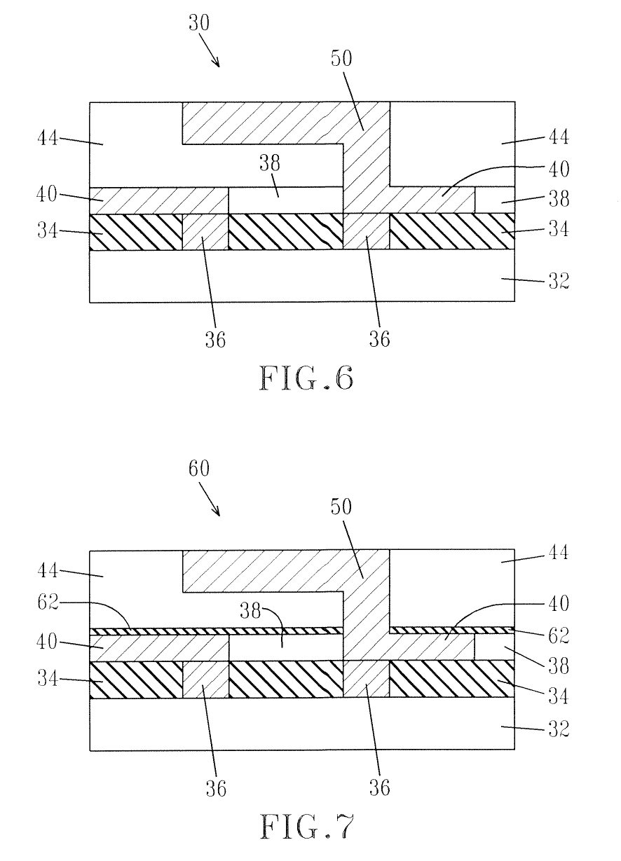

The electronic devices which can include the inventive SiCOH or SiCNH dielectric are shown in FIGS. 6-9. It should be noted that the devices shown in FIGS. 6-9 are merely illustrative examples of the present invention, while an infinite number of other devices may also be formed by the present invention novel methods. It is noted that the SiCNH film of the present invention is used only for layer 62 in these drawings, not for layers 38 or 44.

In FIG. 6, an electronic device 30 built on a silicon substrate 32 is shown. On top of the silicon substrate 32, an insulating material layer 34 is first formed with a first region of metal 36 embedded therein. After a CMP process is conducted on the first region of metal 36, a SiCOH dielectric film 38 of the present invention is deposited on top of the first layer of insulating material 34 and the first region of metal 36. The first layer of insulating material 34 may be suitably formed of silicon oxide, silicon nitride, doped varieties of these materials, or any other suitable insulating materials. The SiCOH dielectric film 38 is then patterned in a photolithography process followed by etching and a conductor layer 40 is deposited thereon. After a CMP process on the first conductor layer 40 is carried out, a second layer of the inventive SiCOH film 44 is deposited by a plasma enhanced chemical vapor deposition process overlying the first SiCOH dielectric film 38 and the first conductor layer 40. The conductor layer 40 may be deposited of a metallic material or a nonmetallic conductive material. For instance, a metallic material of aluminum or copper, or a nonmetallic material of nitride or polysilicon. The first conductor 40 is in electrical communication with the first region of metal 36.

A second region of conductor 50 is then formed after a photolithographic process on the SiCOH dielectric film 44 is conducted followed by etching and then a deposition process for the second conductor material. The second region of conductor 50 may also be deposited of either a metallic material or a nonmetallic material, similar to that used in depositing the first conductor layer 40. The second region of conductor 50 is in electrical communication with the first region of conductor 40 and is embedded in the second layer of the SiCOH dielectric film 44. The second layer of the SiCOH dielectric film is in intimate contact with the first layer of SiCOH dielectric material 38. In this example, the first layer of the SiCOH dielectric film 38 is an intralevel dielectric material, while the second layer of the SiCOH dielectric film 44 is both an intralevel and an interlevel dielectric. Based on the low dielectric constant of the inventive SiCOH dielectric film, superior insulating property can be achieved by the first insulating layer 38 and the second insulating layer 44.

FIG. 7 shows a present invention electronic device 60 similar to that of electronic device 30 shown in FIG. 6, but with an additional dielectric cap layer 62 deposited between the first insulating material layer 38 and the second insulating material layer 44. The dielectric cap layer 62, which comprises SiCNH, can be suitably formed by the fifth embodiment of this invention. The additional dielectric cap layer 62 functions as a diffusion barrier layer for preventing diffusion of the first conductor layer 40 into the second insulating material layer 44 or into the lower layers, especially into layers 34 and 32.

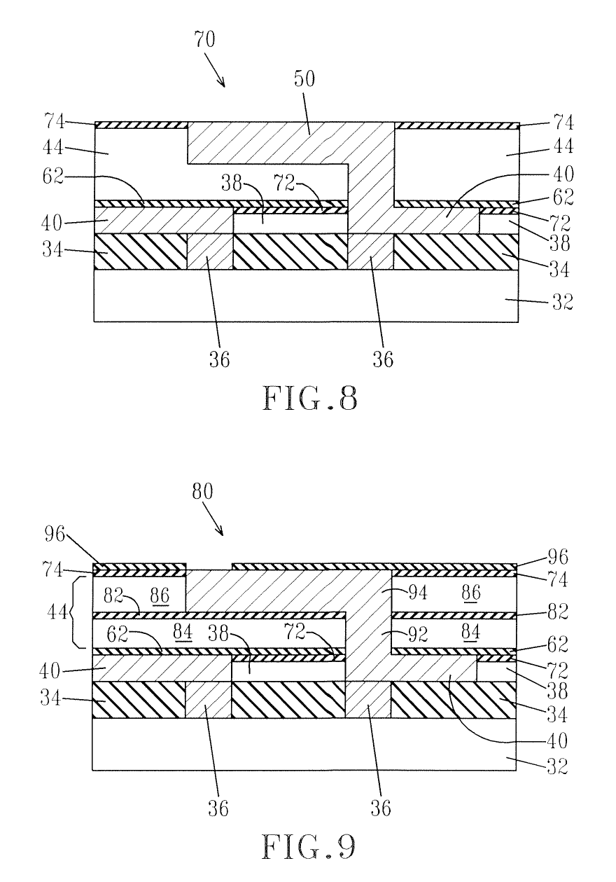

Another alternate embodiment of the present invention electronic device 70 is shown in FIG. 8. In the electronic device 70, two additional dielectric cap layers 72 and 74 which act as a RIE mask and CMP (chemical mechanical polishing) polish stop layer are used. The first dielectric cap layer 72 is deposited on top of the first ultra low k insulating material layer 38 and used as a RIE mask and CMP stop, so the first conductor layer 40 and layer 72 are approximately co-planar after CMP. The function of the second dielectric layer 74 is similar to layer 72, however layer 74 is utilized in planarizing the second conductor layer 50. The polish stop layer 74 can be deposited of a suitable dielectric material such as silicon oxide, silicon nitride, silicon oxynitride, silicon carbide, silicon carbo-oxide (SiCO), and their hydrogenated compounds. A preferred polish stop layer composition is SiCH or SiCOH or SiCNH for layers 72 or 74. A second dielectric layer can be added on top of the second SiCOH dielectric film 44 for the same purposes.

Still another alternate embodiment of the present invention electronic device 80 is shown in FIG. 9. In this alternate embodiment, an additional layer 82 of dielectric material is deposited and thus dividing the second insulating material layer 44 into two separate layers 84 and 86. The intralevel and interlevel dielectric layer 44 formed of the inventive ultra low k material is therefore divided into an interlayer dielectric layer 84 and an intralevel dielectric layer 86 at the boundary between via 92 and interconnect 94. An additional diffusion barrier layer 96 is further deposited on top of the upper dielectric layer 74. The additional benefit provided by this alternate embodiment electronic structure 80 is that dielectric layer 82 acts as an RIE etch stop providing superior interconnect depth control. Thus, the composition of layer 82 is selected to provide etch selectivity with respect to layer 86.

Still other alternate embodiments may include an electronic structure which has layers of insulating material as intralevel or interlevel dielectrics in a wiring structure that includes a pre-processed semiconducting substrate which has a first region of metal embedded in a first layer of insulating material, a first region of conductor embedded in a second layer of the insulating material wherein the second layer of insulating material is in intimate contact with the first layer of insulating material, and the first region of conductor is in electrical communication with the first region of metal, a second region of conductor in electrical communication with the first region of conductor and is embedded in a third layer of insulating material, wherein the third layer of insulating material is in intimate contact with the second layer of insulating material, a first dielectric cap layer between the second layer of insulating material and the third layer of insulating material and a second dielectric cap layer on top of the third layer of insulating material, wherein the first and the second dielectric cap layers are formed of a SiCOH dielectric film of the present invention.

Still other alternate embodiments of the present invention include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor that is in electrical communication with the first region of conductor and is embedded in a third layer of insulating material, the third layer of insulating material is in intimate contact with the second layer of insulating material, and a diffusion barrier layer formed of the dielectric film of the present invention deposited on at least one of the second and third layers of insulating material.

Still other alternate embodiments include an electronic structure which has layers of insulating material as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a reactive ion etching (RIE) hard mask/polish stop layer on top of the second layer of insulating material, and a diffusion barrier layer on top of the RIE hard mask/polish stop layer, wherein the RIE hard mask/polish stop layer and the diffusion barrier layer are formed of the SiCOH or SiCNH dielectric film of the present invention.

Still other alternate embodiments include an electronic structure which has layers of insulating materials as intralevel or interlevel dielectrics in a wiring structure that includes a pre-processed semiconducting substrate that has a first region of metal embedded in a first layer of insulating material, a first region of conductor embedded in a second layer of insulating material which is in intimate contact with the first layer of insulating material, the first region of conductor is in electrical communication with the first region of metal, a second region of conductor in electrical communication with the first region of conductor and is embedded in a third layer of insulating material, the third layer of insulating material is in intimate contact with the second layer of insulating material, a first RIE hard mask, polish stop layer on top of the second layer of insulating material, a first diffusion barrier layer on top of the first RIE hard mask/polish stop layer, a second RIE hard mask/polish stop layer on top of the third layer of insulating material, and a second diffusion barrier layer on top of the second RIE hard mask/polish stop layer, wherein the RIE hard mask/polish stop layers and the diffusion barrier layers are formed of the SiCOH or SiCNH dielectric film of the present invention.

Still other alternate embodiments of the present invention includes an electronic structure that has layers of insulating material as intralevel or interlevel dielectrics in a wiring structure similar to that described immediately above but further includes a dielectric cap layer which is formed of the SiCOH or SiCNH dielectric material of the present invention situated between an interlevel dielectric layer and an intralevel dielectric layer.

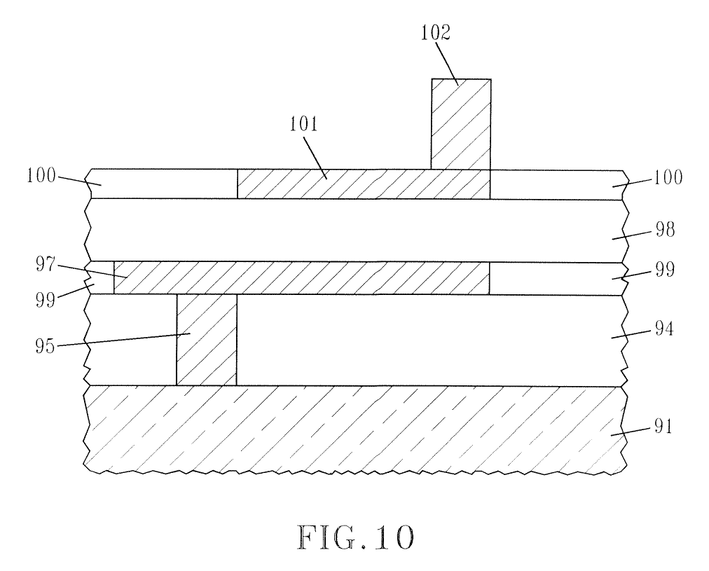

In some embodiments as shown, for example in FIG. 10, an electronic structure containing at least two metallic conductor elements (labeled as reference numerals 97 and 101) and a SiCOH or SiCNH dielectric material (labeled as reference numeral 98). Optionally, metal contacts 95 and 102 are used to make electrical contact to conductors 97 and 101. The inventive SiCOH or SiCNH dielectric 98 provides electrical isolation and low capacitance between the two conductors. The electronic structure is made using a conventional technique that is well known to those skilled in the art such as described, for example, in U.S. Pat. No. 6,737,727, the entire content of which is incorporated herein by reference.

The at least two metal conductor elements are patterned in a shape required for a function of a passive or active circuit element including, for example, an inductor, a resistor, a capacitor, or a resonator.

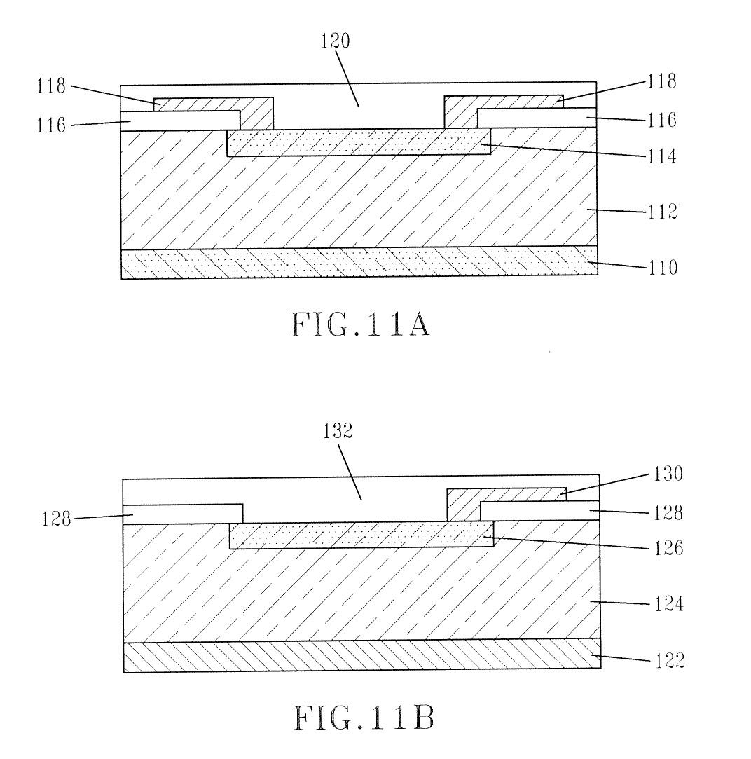

Additionally, the inventive SiCOH or SiCNH can be used in an electronic sensing structure wherein the optoelectronic sensing element (detector) shown in FIG. 11A or 11B is surrounded by a layer of the inventive SiCOH or SiCNH dielectric material. The electronic structure is made using a conventional technique that is well known to those skilled in the art. Referring to FIG. 11A, a p-i-n diode structure is shown which can be a high speed Si based photodetector for IR signals. The n+ substrate is 110, and atop this is an intrinsic semiconductor region 112, and within region 112 p+ regions 114 are formed, completing the p-i-n layer sequence. Layer 116 is a dielectric (such as SiO₂) used to isolate the metal contacts 118 from the substrate. Contacts 118 provide electrical connection to the p+ regions. The entire structure is covered by the inventive SiCOH or SiCNH dielectric material, 120. This material is transparent in the IR region, and serves as a passivation layer.

A second optical sensing structure is shown in FIG. 11B, this is a simple p-n junction photodiode, which can be a high speed IR light detector. Referring to FIG. 11B, the metal contact to substrate is 122, and atop this is an n-type semiconductor region 124, and within this region p+ regions 126 are formed, completing the p-n junction structure. Layer 128 is a dielectric (such as SiO₂) used to isolate the metal contacts 130 from the substrate. Contacts 130 provide electrical connection to the p+ regions. The entire structure is covered by the inventive SiCOH or SiCNH dielectric material, 132. This material is transparent in the IR region, and serves as a passivation layer.

While the present invention has been described in an illustrative manner, it should be understood that the terminology used is intended to be in a nature of words of description rather than of limitation. Furthermore, while the present invention has been described in terms of a preferred and several alternate embodiments, it is to be appreciated that those skilled in the art will readily apply these teachings to other possible variations of the invention.

What is claimed is:

1. A method of forming a dielectric film comprising atoms of Si, C, H and O comprising:
providing a substrate in a reactor chamber;
flowing at least one precursor into said reactor chamber, wherein said at least one precursor is a cyclic carbosilane or oxycarbosilane; and
depositing a dielectric film onto said substrate.

2. The method of claim 1 further comprising adding a flow of a gas to said at least one precursor comprising at least one of O₂, NH₃, CO, CO₂, N₂O, O₃, N₂ and an inert gas.

3. The method of claim 1 wherein said substrate includes a top surface comprised of regions of metal conductors and regions of dielectric.

4. The method of claim 1 wherein said cyclic carbosilane or oxycarbosilane comprises 1,1-dimethyl-1-silacyclopentane, 1,3-disilylcyclobutane, methyl-1-silacyclopentane, silacyclopentane, silacyclobutane, methylsilacyclobutanes, silacyclohexane, methylsilacyclohexanes, tetramethyl-disila-furan, disila-furan, methoxy derivatives of the aforementioned cyclic precursors, or derivatives of disila-furan containing 1, 2, 3 or 4 R groups, where R is selected from methyl, ethyl, vinyl, propyl, allyl, and butyl.

5. The method of claim 1 wherein said cyclic carbosilane comprises an unsaturated ring and includes 1,1-diethoxy-1-silacyclopentene, 1,1-dimethyl-3-silacyclopentene, 1,1-dimethyl-1-silacyclopent-3-ene, 1-sila-3-cyclopentene or vinylmethylsilacyclopentene, or methoxy derivatives of the aforementioned cyclic precursors.

6. The method of claim 1 further comprising adding a flow of a hydrocarbon precursor.

7. The method of claim 6 wherein said hydrocarbon precursor comprises one of bicycloheptadiene, hexadiene, and bifunctional diene hydrocarbon molecules.

8. The method of claim 1 further comprising a SiCOH skeleton precursor selected from an alkoxysilane and a cyclic siloxane.

9. The method of claim 8 wherein the ratio R1 of carbosilane or oxycarbosilane precursor to SiCOH skeleton precursor in the reactor determines a concentration of Si—R—Si bridging carbon in the SiCOH film and R1 is in the range from 0.01 to 100.

10. The method of claim 1 further comprising performing an energetic treatment step after said depositing, said energetic treatment comprises thermal energy, UV light, electron beam irradiation, chemical energy, or a combination thereof.

11. A method of forming a dielectric film comprising atoms of Si, C, H and O comprising:
providing at least a first precursor and a second precursor into a reactor chamber, wherein at least one of the precursors is a hydrocarbon porogen and the other of said precursors is a cyclic carbosilane or oxycarbosilane;
depositing a film comprising a first phase and a second phase; and
removing said porogen from said film to provide a porous dielectric film.

12. A method of forming a dielectric film comprising atoms of Si, C, N and H comprising:
providing a substrate in a reactor chamber;
flowing at least one precursor into said reactor chamber, said at least one precursor is a cyclic compound that contains at least one N atom in a ring structure with Si and C atoms; and
depositing a dielectric film comprising atoms of Si, C, N and H from said at least one precursor.

13. The method of claim 12 further comprising adding a flow of a gas to said at least one precursor comprising at least one of NH₃, CO, CO₂, O₂, N₂O, O₃, N₂ and an inert gas.

14. The method of claim 12 wherein said cyclic precursor is 2,2,5,5-tetramethyl-2,5-disila-1-azacyclopentane, or a related azacyclopentane.

15. The method of claim 12 further comprising adding a flow of a liquid or gaseous hydrocarbon precursor.

16. The method of claim 15 wherein said hydrocarbon precursor comprises one of bicycloheptadiene, hexadiene, and bifunctional diene hydrocarbon molecules.

17. The method of claim 12 further comprising performing an energetic treatment step utilizing thermal energy, UV light, electron beam irradiation, chemical energy, or a combination thereof.

18. The method of claim 12 wherein said SiCNH film comprises between about 5 and about 40 atomic percent of Si; between about 5 and about 50 atomic percent of C; between 0 and about 50 atomic percent of N; and between about 10 and about 55 atomic percent of H.

19. An electronic structure comprising a dielectric cap located on a dielectric material, said dielectric cap comprising atoms of Si, C, N and H and having N bridging located between two Si atoms.

20. The electronic structure of claim 19 wherein said dielectric material comprises atoms of Si, C, O and H having a covalently bonded tri-dimensional network which includes C bonded as Si—CH₃ and also C bonded as Si—R—Si in which R is —[CH₂]ₙ— and wherein n is greater than or equal to one.
